(19) United States
(12) Patent Application Publication
(10) Pub. No.: US 2008/0048196 A1
(43) Pub. Date: Feb. 28, 2008

(54) Component and Process for Manufacturing the Same

(75) Inventors: Andre Strittmatter, Berlin (DE); Lars Reissmann, Berlin (DE); Dieter Bimberg, Berlin (DE)

Correspondence Address: LERNER GREENBERG STEMER LLP, P O BOX 2480, HOLLYWOOD, FL, 33022-2480, US

(73) Assignee: TECHNISCHE UNIVERSITAT BERLIN, Berlin (DE)

(21) Appl. No.: 11/851,909

(22) Filed: Sep. 7, 2007

Related U.S. Application Data
(63) Continuation of application No. PCT/DE2006/000399, filed on Mar. 1, 2006.

(30) Foreign Application Priority Data
Mar. 7, 2005 (DE) DE102005010821.0

(51) Int. Cl. H01L 21/20; H01L 33/00

(52) U.S. Cl. 257/94; 257/615; 438/492; 438/504; 257/E21.09; 257/E33.001

(57) ABSTRACT

An electrical and/or optical component and a process for manufacturing the component achieve especially good quality in the component and especially reliably avoid crystal dislocations in material layers of the component. In the process for producing a component, at least one trench is etched into a substrate, the trench is overgrown laterally by at least one semiconductor layer in such a way that the trench is completely covered by the semiconductor layer while forming a gas-filled, especially air-filled, cavity, and the component is integrated in the semiconductor layer or in a further semiconductor layer applied to the semiconductor layer, with an active region of the component being placed above the cavity.

### CROSS-REFERENCE TO RELATED APPLICATIONS

This is a continuing application, under 35 U.S.C. §120, of copending International Application No. PCT/DE2006/000399, filed Mar. 1, 2006, which designated the United States; this application also claims the priority, under 35 U.S.C. §119, of German Patent Application DE 10 2005 010 821.0, filed Mar. 7, 2005; the prior applications are herewith incorporated by reference in their entirety.

### BACKGROUND OF THE INVENTION

### Field of the Invention

The invention relates to an electrical and/or optical component and a process for manufacturing an electrical and/or optical component, for example an electrical transistor, a laser, a light-emitting diode, a photodetector or an optical waveguide.

One such process is known, for example, from U.S. Pat. No. 5,389,571. In that process, first an AlN intermediate layer is applied to a silicon substrate. GaN layers, from which a light-emitting diode is formed, are then deposited on that AlN intermediate layer. The function of the AlN intermediate layer is to avoid three-dimensional growth of the GaN layers. GaN and silicon have differing lattice constants, so that if the GaN layers grow directly on the silicon substrate, that would lead to three-dimensional growth.

### BRIEF SUMMARY OF THE INVENTION

It is accordingly an object of the invention to provide an electrical and/or optical component and a process for manufacturing the same, which overcome the hereinafore-mentioned disadvantages of the heretofore-known products and processes of this general type and in which the component achieves especially good quality. In particular, crystal dislocations in the material layers of the component should be reliably avoided.

With the foregoing and other objects in view there is provided, in accordance with the invention, a process for manufacturing an electrical and/or optical component, comprising etching at least one trench into a substrate. The trench is overgrown laterally with at least one semiconductor layer so that the trench is completely covered by the semiconductor layer while forming a gas-filled, especially an air-filled cavity. The component is integrated into the semiconductor layer or in an additional semiconductor layer applied onto the semiconductor layer. The active area of the component is placed above the cavity.

One specific advantage of the process according to the invention is that based on an etching of one or more trenches, it becomes possible to have an especially low-dislocation growth of the semiconductor layer. Namely, through the etching of trenches, a non-planar substrate is generated, on which then such semiconductor layers can also be deposited in low-dislocation fashion, with crystal lattice intervals which do not fit into the crystal lattice intervals of the substrate. This is derived from the fact that in the area of the trenches, the deposited semiconductor layers have no contact with the substrate, so that in these areas, no lattice stresses can appear.

A further considerable advantage of the process according to the invention relates to improved properties of the component, since it is placed over the gas-filled cavity. Both in optical and in electrical components, it is normally an advantage if the electrical and/or electromagnetic fields or waves generated by the components cannot penetrate into the substrate, since such a penetration can lead to formation of additional damping and/or formation of additional capacitative effects. Such parasitic effects are avoided in the process according to the invention, because the component is deliberately placed in an area that is made distant from the substrate by a gas such as air, thus achieving an electrical and optical uncoupling from the substrate.

As a result, with the process according to the invention, a synergy effect appears: due to the overgrowth of the previously etched trenches, on one hand, the crystal growth of the semiconductor layer to be grown is improved. On the other hand, this creates areas in which the components are placed while improving their electrical and/or optical properties.

Silicon is known to be a very suitable material for manufacture of electrical components, so that it can be viewed as an advantage if a silicon substrate is used as the substrate.

In order to form electro-optical components, preferably a nitride layer is deposited as the semiconductor layer, especially based on one or more Group III elements of the periodic table. For example, GaN layers or layers containing GaN can be deposited on the substrate as the semiconductor layer.

GaN layers or layers containing GaN can be grown with very little dislocation on a silicon substrate, if the surface of the silicon substrate has a (111) orientation and the longitudinal direction of the cavity is placed along a (1-1 0) substrate orientation or a (1 1-2) substrate orientation.

If the component is an optoelectronic component, then the optically active zone of the optoelectronic component is preferably placed above the cavity.

In the case of an optoelectronic component with an optical waveguide, the longitudinal direction of the waveguide preferably is placed parallel to the longitudinal direction of the cavity.

For example, a light-emitting component, especially a light-emitting diode or a laser, or a detector element, especially a photodiode, can be produced as the optoelectronic component. If the optoelectronic component is an edge-emitting laser, then its emission direction preferably is placed parallel to the longitudinal direction of the cavity.

A transistor, especially a field-effect transistor, can also be produced as the component. In this case, the channel area of the transistor preferably is placed above the cavity. The channel area can be disposed to be perpendicular to, parallel to, or at any other angle to, the longitudinal direction of the cavity.

In other respects, above the cavity, both a transistor and an optoelectronic component can be produced, with the two components electrically connected with each other while forming one optoelectronic component.

While the semiconductor layer is growing, to avoid disturbances in the growth which derive from an outward diffusion of atoms from the substrate, after the trench is etched, the substrate preferably is provided with a passivation layer and only after that is the semiconductor layer precipitated directly or indirectly on the passivation layer.

Disturbing substrate atoms are prevented in especially reliable fashion from diffusing outward, if the passivation layer is preferably deposited in such a way that all of the lateral wall areas of the etched trench are completely covered by the passivation layer. This ensures that no contaminations can emerge from these lateral wall areas either.

For example, the passivation layer can be used directly as a nucleation layer for the growth of the semiconductor layer. In other respects, the passivation layer can be formed by a conversion of the substrate surface.

The passivation layer preferably is configured to be electrically conducting in order to make possible a contact of the component through the substrate.

For example, the passivation layer can be formed by a single layer, or alternatively by a packet of layers made of several individual passivation layers. Preferably, an AlN or an AlₓGa₁₋ₓN layer, or a layer packet with at least one AlN layer and at least one AlₓGa₁₋ₓN layer, is precipitated on the substrate.

For example, initially an AlAs layer can be deposited for formation of the passivation layer. This AlAs layer is then preferably nitrided while forming an AlN layer.

For example, an AlₓGa₁₋ₓN layer as a further passivation layer or as a semiconductor layer or “utilization layer” can be deposited on the AlN passivation layer for formation of the component.

In order to avoid crystal dislocations occurring with thicker GaN semiconductor layers or with thicker semiconductor layers containing GaN, during the growth of the GaN semiconductor layer or the GaN-containing semiconductor layer, preferably the growth is interrupted at least once, and with each interruption, an intermediate layer is grown. Preferably, this intermediate layer is constituted in such a way that it generates a compressive bracing.

For example, AlN layers can be grown as intermediate layers. Each intermediate layer is between 7 nm and 9 nm, preferably approximately 8 nm, thick, for example.

The intermediate layers are preferably grown at a temperature between 900 and 1100 degrees Celsius, preferably at 1000 degrees Celsius. In what follows, all temperatures are given in degrees Celsius, if nothing else is indicated in an individual instance.

In regard to particularly good crystal growth, it is viewed as advantageous if a multiplicity of parallel trenches is etched into the substrate, whereby the interval between the trenches is chosen to be smaller than the width of the trenches. For example, the trenches are at least 1 μm, preferably 2-4 μm deep. The trenches preferably are at least 2 μm, preferably 5 μm to 10 μm wide. The webs that are formed between every two adjoining trenches are at most 2 μm, and preferably less than 1 μm wide.

In an instance where very small components such as transistors are placed above the cavity, it is advantageous to place these components on the outer edge of the cavity, to facilitate release of waste heat from the component into the substrate. Additionally, consideration is to be given to selecting the width of the trenches to be smaller than the minimum width mentioned, to make possible thermal diffusion to both cavity edges. Optimal thermal diffusion is achieved if the cavity is only slightly wider than the width of the component.

In regard to an especially small crystal dislocation thickness, it is viewed as advantageous if the trenches are placed so that the webs remaining standing between the trenches have a pillar structure, preferably that of a hexagonal lattice.

For example, a silicon-on-insulator (SOI) can be used as the substrate. The trench or trenches in this case can be etched, for example into a trenched insulation layer, that functions as a stop for the etching. SOI material produces especially good insulation, particularly for transistors.

In addition, the invention relates to an electrical and/or optical component.

Regarding such a component, the task that is the basis of the invention is to obtain particularly good component behavior.

With the objects of the invention in view, there is also provided an electrical and/or optical component, comprising a substrate with at least one trench. The trench is overgrown with at least one semiconductor layer so that it is completely covered by the semiconductor layer while forming a gas-filled, especially an air-filled cavity. The active area of the component is integrated into the semiconductor layer or a further semiconductor layer applied to the semiconductor layer. The active area of the component is placed above the cavity.

Therefore, according to the invention, a component is provided with a substrate and at least one trench, whereby the trench is laterally overgrown by at lest one semiconductor layer so that it is completely covered by the semiconductor layer while forming a gas-filled, especially air-filled, cavity. The active area of the component is integrated in the semiconductor layer or in a further semiconductor layer applied on the semiconductor layer and, preferably exclusively, placed above the cavity. The term “active area” is understood, for example, to mean a light-emitting element such as a laser or a light-emitting diode of the light-generating area, with a field-effect transistor, the trench area, and with a waveguide, the area guiding the wave.

Regarding the advantages of the component according to the invention, reference is made to the above explanations in connection with the process according to the invention. The same holds true for the embodiments of the component defined in the dependent claims.

The deposition of a passivation layer that was already described above in detail represents an independent inventive concept. Deposition of the passivation layer prevents contaminations from emerging from the substrate during growth of the semiconductor layer, so that the growth of the semiconductor layer is not disturbed, and the trench is reliably coated with very little dislocation. Accordingly, a process is thus regarded as inventive in which at least one trench is etched into a substrate, after the trench is etched, the substrate is provided with a passivation layer, the passivation layer is deposited in such a way that all of the lateral wall areas of the etched trench are completely covered by the passivation layer, the trench is laterally overgrown by the semiconductor layer so that it is completely covered by the semiconductor layer while forming a gas-filled, especially an air-filled cavity, and the component is integrated in the semiconductor layer or in a further semiconductor layer applied to the semiconductor layer.

The deposition of intermediate layers during deposition of a GaN semiconductor layer or a semiconductor layer containing GaN, represents a further, independent aspect of the invention. Through the deposition of intermediate layers, crystal stresses are at least reduced in the semiconductor layer, so that the trench is overgrown with little dislocation. Accordingly, a process is also to be regarded as inventive in which at least one trench is etched into a substrate, and the trench is overgrown laterally by at least one GaN semiconductor layer or a semiconductor layer containing GaN, so that the trench is completely covered by the semiconductor layer while forming a gas-filled, especially air-filled, cavity, during the growth of the semiconductor layer on the substrate, the growth is interrupted at least once, and during each interruption, an intermediate layer is grown, and in which the component is integrated in the semiconductor layer or in a further semiconductor layer applied to the semiconductor layer.

Other features which are considered as characteristic for the invention are set forth in the appended claims.

Although the invention is illustrated and described herein as embodied in a component and a process for manufacturing the same, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a sectional view of a first embodiment example of a component according to the invention, with the aid of which a first version of the process according to the invention is explained;

FIG. 2 is a sectional view of a second embodiment example of the invention, in which a substrate surface is passivated;

FIG. 3 is a sectional view of a third embodiment example of the invention, in which an intermediate layer is deposited;

FIG. 4 is a sectional view of a fourth embodiment example of the invention with a laser structure; and

FIG. 5 is a sectional view of a fifth embodiment example of the invention with a field-effect transistor structure.

### DETAILED DESCRIPTION OF THE INVENTION

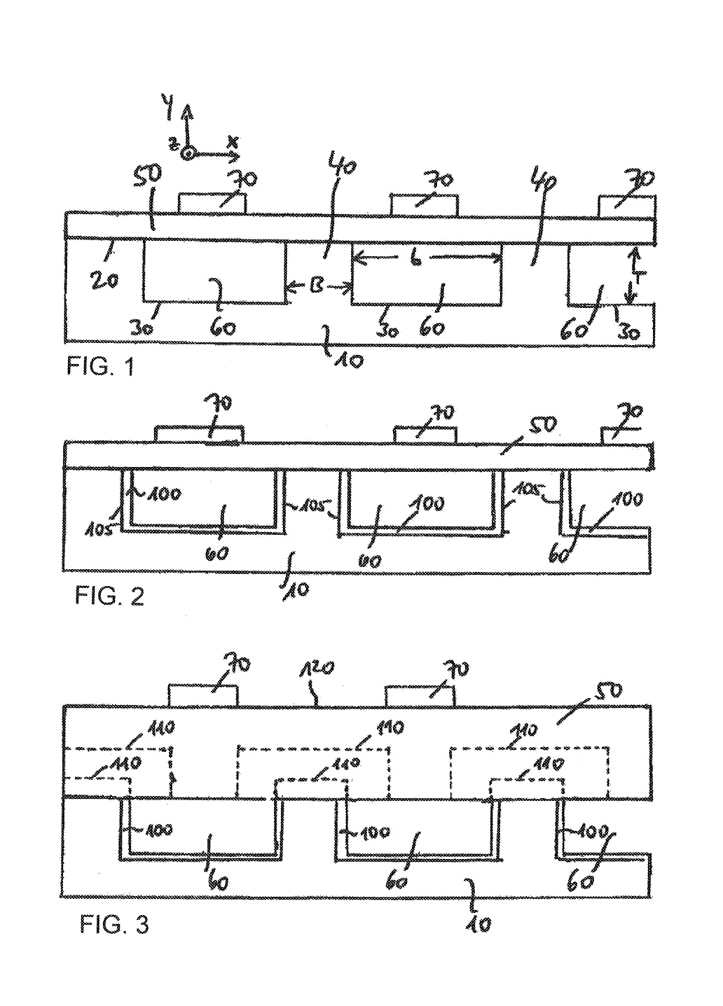

Referring now in detail to the figures of the drawings, in which the same reference symbols are used for identical or comparable components, and first, particularly, to FIG. 1 thereof, there is seen a silicon substrate 10, having a substrate surface 20 which has a (111) orientation. In order to produce the structure depicted in FIG. 1, first a photolithographically defined photoresist mask in the form of strips oriented parallel in the silicon [1-10] direction is applied to the surface 20 of the silicon substrate 10. In the FIG. 1 illustration, these strips would extend in the z direction. These strips are 2 μm wide, and the distance between the respective strips is 3 μm. The silicon surface 20 is etched between the photoresist strips to a depth of T=2 μm by dry etching with an SF₆:O₂ plasma. The surface 20 of the silicon substrate 10 is then provided with trenches that are designated with reference numeral 30 in FIG. 1. A width b of the trenches is about b=3 μm. Webs 40 between the trenches 30 have a width B=2 μm.

After etching of the trenches 30, the silicon substrate 10 is cleaned in acetone and propyl alcohol and subjected to etching with a mixture of H₂SO₄:H₂O₂:H₂O and a buffered HF solution, with deionized super-clean water used to rinse it sufficiently between each individual step.

Then a semiconductor layer, such as a gallium nitrite semiconductor layer 50, is deposited on to the silicon substrate 10 which is thus cleaned. All suitable chemical compounds with Group III or Group V elements can be used as initial materials for the epitaxy, that result in deposition of the desired gallium nitrite semiconductor layer. What is meant by suitable in this connection is that the compounds are stable at room temperature, but are decomposable at the temperatures T>100° C. that are customary for nitrite epitaxy. For example, trimethyl gallium, trimethyl aluminum, ammonia and arsine can be used. An organometallic gas phase epitaxy (MOCVD) or some other epitaxy method such as MBE or HVPE, for example, can be used for the epitaxy.

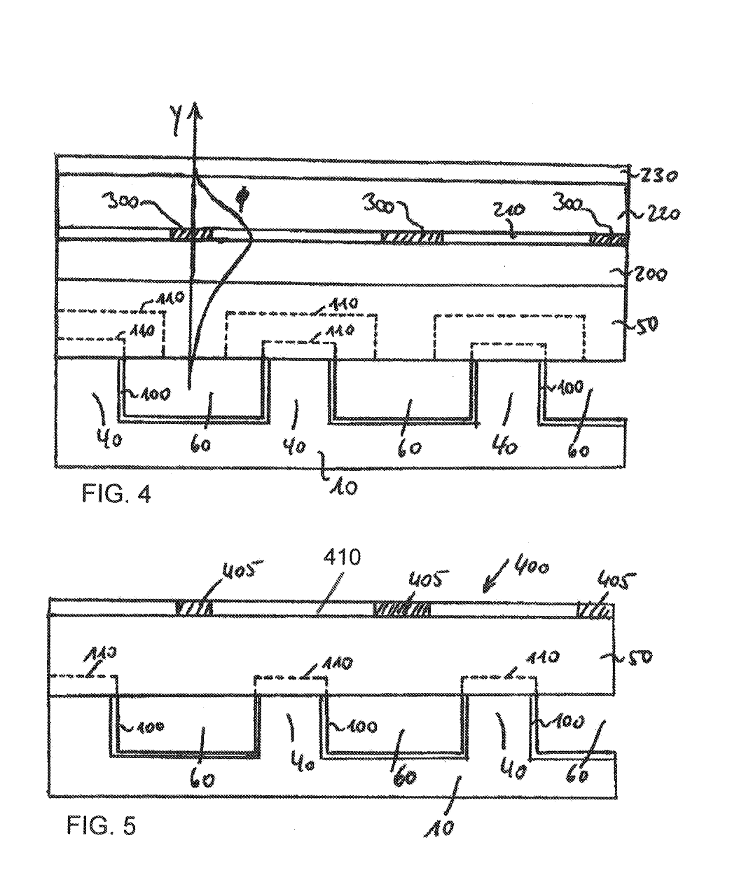

The gallium nitrite semiconductor layer 50 is deposited in such a way that the trenches 30 are overgrown laterally. Due to this lateral overgrowth, on the non-planar silicon substrate 10, a closed, planar covering layer is formed, beneath which gas-filled, and especially air-filled cavities 60 are formed. Electrical, electronic or electro-optical components 70, for example, can be placed in a customary, known manner onto the semiconductor layer 50, which is thus deposited, through further deposition processes. The components 70 are disposed on the semiconductor layer 50 in such a way that they lie above the gas-filled cavities 60. Placement of the components 70 above the cavities 60 results in especially favorable electrical and/or optical behavior of the components, which will be explained in detail below in connection with the embodiment examples of FIGS. 4 and 5.

FIG. 2 shows a second embodiment example of the invention. One can recognize that first a passivation layer 100 is applied on the silicon substrate 10 after etching of the trench 30, before the gallium nitrite semiconductor layer 50 is deposited on the entire surface of the substrate 10.

The passivation layer 100 is formed as follows: first, an aluminum arsenite (AlAs) layer, about 2 nm thick, is deposited on the non-planar silicon substrate 10, at a temperature of about 430° C. Then, an AlAs layer, about 30 nm thick, is grown at a temperature of 825° C. The aluminum arsenite layer packet thus formed is nitrided by adding ammonia at a temperature of about 960° C., so that an aluminum nitrite (AlN) layer or surface is obtained.

Then, an approximately 50 nm thick AlₓGa₁₋ₓN layer (x>0) is deposited at a temperature of about 1150° C. on the aluminum nitrite surface, which is thus formed. Preferably, the reactor pressure is about 50 mbar, and the growth rate is preferably greater than 0.3 μm per hour. This layer is deposited by adding in TMAl (trimethyl aluminum) and TMGa (trimethyl gallium) as well as ammonia. The growth rate of the AlₓGa₁₋ₓN layer results from the corresponding supply of TMA1 and TMGa. Such layers have a high degree of adherence onto the silicon surface 20 of the silicon substrate 10, that the entire surface, especially even the lateral walls 105 of the trenches 30, are completely covered.

The aluminum nitrite layer packet formed in this way and the AlₓGa₁₋ₓN layer placed on it, is designated in FIG. 2 as the passivation layer 100. Then, a GaN layer 50 is grown onto this passivation layer 100 as a semiconductor layer, by adding TMGa and ammonia at a temperature of 1125° C. with a vertical growth rate of 0.5 μm per hour and a reactor pressure of 200 mbar. After the lateral growth fronts have closed and the trenches 30 are closed while forming the gas-filled cavities 50, a customary semiconductor structure for transistors, light-emitting diodes or laser diodes made of (In,Ga,Al)N layers can be deposited as semiconductor components.

FIG. 3 shows a third embodiment example of the invention. One can recognize that with the deposition of the gallium nitrate semiconductor layer 50, additional intermediate layers 110 are deposited.

The FIG. 3 structure is produced in the following steps: The substrate 10 is first heated in a nitrogen atmosphere to a temperature of 720° C. Growth starts by preliminary streaming with TMA1 for 10 seconds, and then mixing ammonia in at a flow rate of 1.5 liters per minute, at a reactor pressure of approximately 50 mbar. The AlN nucleation layer that results simultaneously serves as a passivation layer 100 and therefore is grown to be 50 nm thick.

The growth of the gallium nitrite semiconductor layer 50 by adding TMGa and ammonia at a temperature of 125° C. and a reactor pressure of 200 mbar, as well as a vertical growth rate of 0.5 μm per hour, then begins. The growth of the GaN layer is interrupted each time the layer has grown by 0.5 μm, thus a growth time of about 60 minutes of vertical GaN growth, and an AlN layer, about 8 nm thick, is grown as an intermediate layer 110 at a temperature of 1000° C. and a reactor pressure of 50 mbar, as well as a growth rate of 160 nm per hour onto the GaN surface. Then, a GaN layer is again grown for 60 minutes. This GaN/AlN deposition is repeated often enough that a closed GaN surface 120 results, onto which the then suitable component 70 can be applied or deposited.

In the embodiment example of FIG. 3, two intermediate layers 110 are accommodated in the semiconductor layer 50. Naturally, the number of intermediate layers 110 is to be selected in such a way that the gallium nitrite semiconductor layer 50 grows with as few dislocations as possible.

FIG. 4 shows a fourth embodiment example of the invention. In this embodiment, optical components in the form of three lasers 300 are applied onto the gallium nitrite semiconductor layer 50.

In order to produce the laser structure depicted in FIG. 4, initially the silicon substrate 10 is provided with the trenches 30, and then passivated with the passivation layer 100. Then, a gallium nitrite semiconductor layer 50 is deposited on the passivated silicon surface 20, by which the trenches 30 are overgrown while forming gas-filled cavities 60. While the gallium nitrite semiconductor layer 50 is being deposited, intermediate layers 110 are deposited, to avoid crystal dislocations during the growth of the gallium nitrite semiconductor layer 50. After the trenches 30 are completely closed, first an n-doped contact layer 200 is applied on the gallium nitrite semiconductor layer 50. A light-emitting layer 210 is deposited on the n-doped contact layer 200, and a waveguide cover layer 220 is deposited on the light-emitting layer 210. Then, a p-doped contact layer 230 is deposited onto the waveguide cover layer 220 and forms an upper electrode layer of the laser structure.

The laser structure of FIG. 4 includes a total of three edge-emitting lasers 300, each of which emits light parallel to the longitudinal direction of the trenches 30 or parallel to the longitudinal direction of the gas-filled cavities 60. The optical field distribution, in the y-direction, of the three lasers is also schematically shown in FIG. 4. One can recognize that the optical field distribution φ extends into the gas-filled cavity 60. However, due to the high refractive index jump between the semiconductor material and the gas, it stays separated from the silicon substrate 10. Due to the fact that the optical field distribution cannot extend in as far as the silicon substrate, the silicon substrate 10 prevents an additional light damping or waveguide damping.

In order to produce the laser structure of FIG. 4, in particular: the laterally overgrown gallium nitrite semiconductor layer 50 is deposited in accord with the process described with regard to FIGS. 1, 2 and 3, whereby the surface 20 of the silicon substrate 10 is passivated by a passivation layer 100 in the form of a 50 nm-thick AlN nucleation layer. The gallium nitrite semiconductor layer 50 is deposited on this passivation layer 100, with additionally an 8-nm-thick AlN intermediate layer 110 being deposited exactly when 500 nm of gallium nitrite has grown in the vertical direction. This process is repeated until the resulting gallium nitrite semiconductor layer 50 completely closes off the trenches 30 and the gas-filled cavities 60 are completely covered.

The lasers 300, which were already mentioned and which include the above-described layers 200 to 230, are grown on the gallium nitrite semiconductor layer, which is thus obtained and has few defects. Further processes are necessary to produce the laser diodes 300 after completion of epitaxy, which limit the vertical flow and/or the lateral guiding of optical waves to the area above the gas-filled cavities 60, which is shown in FIG. 4 by hatched zones 300. These additional processes may include etching processes, for example, for defining a ribbed waveguide or implantation processes for defining appropriate current paths. However, what is important is that the lasers 300 as well as the optical waveguides that are connected with the lasers 300 are directed so that the light propagates above and, if necessary, within the gas-filled cavities 60, and in particular along the longitudinal direction of the cavities 60. Appropriate configuration of the lasers 300 as well as appropriate configuration of the light propagation direction ensures that the light cannot propagate within the silicon substrate 10. Avoiding a propagation of the light within the silicon substrate 10 prevents an additional waveguide damping by the silicon substrate 10. In connection with the additional light damping to be avoided due to the silicon substrate 10, reference should be made, in particular, to the fact that silicon is strongly absorbing at wavelengths below 1.1 μm. Thus, with the structure of FIG. 4, if light is generated with wavelengths below 1.1 μm and/or guided through waveguides, then it is especially important that the guiding of optical waves remain spatially separated from the silicon substrate 10. This is attained by appropriate placement of the optical components, such as a laser, light-emitting diode and waveguide, above the gas-filled cavities 60.

A further advantage of placing the lasers 300 above the gas-filled cavities 60 is seen in that mirror facets of the lasers 300 also can be generated through crystal cleavage instead of expensive etching processes. In addition, due to the relatively low-dislocation growth of the gallium nitrite semiconductor layer 50, a very low-dislocation and high-value growth of laser layers is made possible, so that the electrical properties of the laser are also very good.

FIG. 5 shows a fifth embodiment example of the invention. In this fifth embodiment example, a field effect transistor structure 400 with multiple field effect transistors 405 is deposited on the gallium nitrite semiconductor layer 50. The laterally overgrown semiconductor nitrite layer 50 is produced according to the embodiment examples of FIGS. 1 to 4, with the surface 20 of the non-planar silicon substrate 10 being passivated after deposition of the nucleation layer through the use of a 50-nm-thick AlN layer. Then a GaN layer is grown vertically to a thickness of 500 nm on the ribs 40, and then an 8-nm-thick AlN intermediate layer 110 is deposited. The GaN layer that now follows is principally laterally grown, until the GaN layer closes, so that the GaN thickness remains smaller than about 1 μm over the AlN intermediate layer 110. An undoped, approximately 30-nm-thick AlGaN covering layer 410 is grown over the entire surface of the low-defect gallium nitrite semiconductor layer 50, which is thus obtained. The boundary layer between the gallium nitrite semiconductor layer 50 and the AlGaN covering layer 410 is the electrically active zone of the field effect transistor structure 400. The conductivity of the field effect transistor structure 400 is produced by polarization charges.

In order to produce the transistor structure 400 of FIG. 5, after epitaxy has been carried out and completed, further processes are necessary that limit the charge carrier channel of the field effect transistor 405 to the area above gas-filled cavity 60. For this purpose, the photolithographic definitions of the contact areas (source-gate-drain) must be limited to the corresponding laterally overgrown areas or the gas-filled cavities 60. This is indicated in FIG. 5 by the hatched areas.

One substantial advantage of the configuration of the transistors 405 above the gas-filled cavities 60 is that due to the gas filling, an electrical separation from the silicon substrate 10 is achieved, so that parasitic capacitances through an electrical coupling to the silicon substrate 10 are avoided. This is because the gas-filled cavities 60 evoke a high electrical insulation. The fact that the gas-filled cavities 60 avoid parasitic capacitances to the silicon substrate 10 and in it, causes the customarily RC-limited limit frequency of the transistors 405 to be considerably increased. Despite that, the transistors 405 still adjoin the silicon substrate 10, functioning as a thermal ground, closely enough that thermal losses and waste heat of the transistors 405 can be transferred off into the substrate 10.

In other respects, through the use of the very low-dislocation growth of the gallium nitride layer 50, what is also attained is that in the channel area of the transistors 405, relatively few crystal dislocations appear. An additional charge carrier scattering through dislocations is also avoided, by which the transit-time-limited limit frequency of the transistors 405 is considerably raised.

Transistors are very small components, and therefore the trenches 30 and thus the cavities 60 are preferably selected to be as narrow as possible, for example little larger than the transistors 405, to ensure as good thermal diffusion as possible.

1. A process for manufacturing an electrical and/or optical component, the process comprising the following steps:
etching at least one trench into a substrate;
laterally overgrowing the trench with at least one semiconductor layer and completely covering the trench with the semiconductor layer while forming a gas-filled, especially air-filled, cavity;
integrating an optoelectronic component into the semiconductor layer or in an additional semiconductor layer applied onto the semiconductor layer; and
placing an active region of the component above the cavity.

2. The process according to claim 1, which further comprises producing an optoelectronic element with a waveguide as the component, and placing an optically active zone of the optoelectronic element above the cavity.

3. The process according to claim 2, which further comprises aligning a longitudinal direction of the waveguide parallel to a longitudinal direction of the cavity.

4. The process according to claim 2, which further comprises producing an edge-emitting laser as the optoelectronic component, having a direction of emission extending parallel to a longitudinal direction of the cavity.

5. The process according to claim 1, which further comprises producing a transistor as the component.

6. The process according to claim 5, which further comprises producing a field-effect transistor as the transistor, having a channel area placed above the cavity, and providing a silicon substrate as the substrate.

7. The process according to claim 6, which further comprises providing a surface of the substrate with a (111) orientation and a longitudinal direction of the cavity arrayed along a (1-1 0) substrate orientation or a (1 1-2) substrate orientation.

8. The process according to claim 7, which further comprises:
after etching of the trench, providing the substrate with a passivation layer and depositing the semiconductor layer directly or indirectly on the passivation layer;
completely covering all lateral wall areas of the etched trench with the passivation layer during deposition of the passivation layer; and
depositing a GaN layer or a layer containing GaN as the semiconductor layer on the substrate.

9. The process according to claim 8, which further comprises using the passivation layer as a nucleation layer for growth of the semiconductor layer.

10. The process according to claim 8, which further comprises forming the passivation layer by a conversion of the surface of the substrate.

11. The process according to claim 8, which further comprises depositing an AlN layer or an AlₓGa₁₋ₓN layer or a layer packet with at least one AlN layer or at least one AlₓGa₁₋ₓN layer as the passivation layer on the substrate.

12. The process according to claim 8, which further comprises initially depositing an AlAs layer and then nitriding the AlAs layer while forming an AlN layer, to form the passivation layer.

13. An electrical and/or optical component, comprising:
a substrate having at least one trench;
at least one semiconductor layer laterally overgrown on said trench, completely covering said trench and forming a gas-filled, especially air-filled, cavity; and
an active region integrated into said semiconductor layer or a further semiconductor layer applied to said semiconductor layer, said active region disposed above said cavity.

14. The component according to claim 13, wherein the component is an optoelectronic component having a waveguide with a longitudinal direction parallel to a longitudinal direction of said cavity.

15. The component according to claim 13, wherein the component is selected from the group consisting of a light-emitting element, a light-emitting diode, a laser, a detector element and a photodiode.

16. The component according to claim 14, wherein the component is an edge-emitting laser having an emission direction parallel to the longitudinal direction of the cavity.

17. The component according to claim 13, wherein the component is a transistor.

18. The component according to claim 17, wherein said transistor is a field-effect transistor having a channel area disposed above said cavity.

19. The component according to claim 13, wherein the component is an optoelectronic component including a transistor and an optoelectronic component disposed above said cavity and electrically interconnected.

20. A process for manufacturing a component, the process comprising the following steps:
etching at least one trench into a substrate;
after etching the trench, providing the substrate with a passivation layer by depositing the passivation layer to completely cover all lateral wall areas of the etched trench with the passivation layer;
depositing at least one semiconductor layer directly or indirectly onto the passivation layer, and laterally overgrowing the trench with the semiconductor layer to completely cover the trench with the semiconductor layer while forming a gas-filled, especially air-filled cavity; and
integrating the component in the semiconductor layer or in a further semiconductor layer applied to the semiconductor layer.

21. The process according to claim 20, which further comprises forming a nucleation layer for growth of the semiconductor layer, with the passivation layer.

22. The process according to claim 20, which further comprises forming the passivation layer by conversion of a surface of the substrate.

23. The process according to claim 20, which further comprises depositing an AlN layer or an AlₓGa₁₋ₓN layer or a layer packet with at least one AlN layer and at least one AlₓGa₁₋ₓN layer, as the passivation layer on the substrate.

24. A process for manufacturing a component, the process comprising the following steps:
etching at least one trench into a substrate;
overgrowing the substrate laterally with at least one GaN semiconductor layer or a semiconductor layer containing GaN to completely cover the trench with the semiconductor layer while forming a gas-filled, especially air-filled, cavity;
interrupting the growth of the semiconductor layer on the substrate at least once and growing a respective intermediate layer with each interruption; and
integrating the component in the semiconductor layer or in a further semiconductor layer applied to the semiconductor layer.

25. The process according to claim 24, which further comprises generating a compressive bracing with the intermediate layer.
